(19) United States
(12) Patent Application Publication
(10) Pub. No.: US 2026/0033355 A1
(43) Pub. Date: Jan. 29, 2026

(54) SEMICONDUCTOR PACKAGE

(71) Applicant: Samsung Electronics Co., Ltd., Suwon-si (KR)

(72) Inventors: Yongjin Seol, Suwon-si (KR); Inwon O, Suwon-si (KR); Deokhee Han, Suwon-si (KR)

(21) Appl. No.: 19/061,241

(22) Filed: Feb. 24, 2025

(30) Foreign Application Priority Data
Jul. 23, 2024 (KR) 10-2024-0096895

(51) Int. Cl. H01L 23/538; H01L 23/00; H01L 23/31; H01L 23/373; H01L 25/03

(52) U.S. Cl. CPC H01L 23/5385; H01L 23/3107; H01L 23/373; H01L 24/32; H01L 25/03; H01L 2224/32225

(57) ABSTRACT

A semiconductor package includes a redistribution layer (RDL) including a redistribution wiring structure, a first semiconductor chip on the RDL and electrically connected to the redistribution wiring structure, a heat dissipation member in contact with an upper surface of the first semiconductor chip, a conductive post on the RDL and spaced apart from the first semiconductor chip in a horizontal direction, the conductive post being electrically connected to the redistribution wiring structure, a first molding member on the RDL configured to cover at least a portion of a sidewall of the first semiconductor chip and a sidewall of the conductive post, a package substrate in contact with an upper surface of the heat dissipation member and electrically connected to the conductive post, a second semiconductor chip on and electrically connected to the package substrate, and a second molding member on the package substrate and configured to cover the second semiconductor chip.

### CROSS-REFERENCE TO RELATED APPLICATION

This application claims priority under 35 U.S.C. § 119 to Korean Patent Application No. 10-2024-0096895, filed on Jul. 23, 2024 in the Korean Intellectual Property Office (KIPO), the contents of which are herein incorporated by reference in their entirety.

### FIELD

The present invention relates to semiconductor packages and a methods of manufacturing the same.

### BACKGROUND

In a method of manufacturing a semiconductor package, a first semiconductor chip is on a first redistribution layer (RDL), a molding layer or member is formed on the first RDL to cover the first semiconductor chip, a second RDL is formed on the molding member, and a second semiconductor chip is on the second RDL.

Heat generated from the first semiconductor chip is not emitted well through the molding member, and thus the characteristics of the semiconductor package may be deteriorated.

### SUMMARY

Some embodiments provide a semiconductor package having enhanced electrical characteristics.

Some embodiments provide a method of manufacturing a semiconductor package having enhanced electrical characteristics.

According to some embodiments, there is provided a semiconductor package. The semiconductor package may include a redistribution layer (RDL) including a redistribution wiring structure, a first semiconductor chip on the RDL and electrically connected to the redistribution wiring structure, a heat dissipation member in contact with an upper surface of the first semiconductor chip, a conductive post on the RDL and spaced apart from the first semiconductor chip in a horizontal direction, the conductive post being electrically connected to the redistribution wiring structure, a first molding member on the RDL configured to cover at least a portion of a sidewall of the first semiconductor chip and a sidewall of the conductive post, a package substrate in contact with an upper surface of the heat dissipation member and electrically connected to the conductive post, a second semiconductor chip on and electrically connected to the package substrate, and a second molding member on the package substrate and configured to cover the second semiconductor chip.

According to some embodiments, there is provided a semiconductor package. The semiconductor package may include a redistribution layer (RDL) including a redistribution wiring structure, a first semiconductor chip on the RDL and electrically connected to the redistribution wiring structure, a heat dissipation member in contact with an upper surface of the first semiconductor chip, a conductive post on the RDL and spaced apart from the first semiconductor chip in a horizontal direction, the conductive post being electrically connected to the redistribution wiring structure, a first molding member on the RDL and configured to cover sidewalls of the first semiconductor chip, the heat dissipation member, and the conductive post, a bonding layer structure in contact with upper surfaces of the first molding member, the heat dissipation member, and the conductive post, the bonding layer structure including a bonding pattern structure in the bonding layer structure and in contact with the upper surface of the conductive post, a package substrate in contact with upper surfaces of the bonding layer structure and the bonding pattern structure, a second semiconductor chip on and electrically connected to the package substrate, and a second molding member on the package substrate and configured to cover the second semiconductor chip.

According to some embodiments, there is provided a semiconductor package. The semiconductor package may include a redistribution layer (RDL) including a redistribution wiring structure, a first semiconductor chip on the RDL and electrically connected to the redistribution wiring structure, a conductive post on the RDL, spaced apart from the first semiconductor chip in a horizontal direction, and electrically connected to the redistribution wiring structure, a first molding member on the RDL and including a first portion configured to cover a sidewall of the first semiconductor chip and having a first upper surface and a second portion configured to cover a sidewall of the conductive post and having a second upper surface that is lower than the first upper surface of the first portion, a package substrate on the first semiconductor chip and the first molding member and electrically connected to the conductive post, a second semiconductor chip on and electrically connected to the package substrate, and a second molding member on the package substrate and configured to cover the second semiconductor chip.

According to some embodiments, there is provided a method of manufacturing a semiconductor package. In the method, forming a conductive post on a redistribution layer (RDL) including a redistribution wiring structure, the conductive post being electrically connected to the redistribution wiring structure. Then forming a first semiconductor chip on the RDL to be spaced apart from the conductive post, the first semiconductor chip being electrically connected to the redistribution wiring structure. Then forming a molding member on the RDL to cover at least a portion of a sidewall of the first semiconductor chip and a sidewall of the conductive post. Then forming a heat dissipation member on an upper surface of the first semiconductor chip. Then mounting an upper package to contact an upper surface of the heat dissipation member, the upper package being electrically connected to the conductive post.

In example embodiments, when the upper package is mounted to contact the upper surface of the heat dissipation member, a first conductive connection member may be formed to contact an upper surface of the conductive post. The upper package may be mounted such that a second conductive connection member on a lower surface of the upper package may contact the first conductive connection member. A reflow process may be performed so that the first and second conductive connection members may be merged with each other to form a third conductive connection member.

In example embodiments, after forming the third conductive connection member, an underfill member may be formed between the molding member and the upper package to cover a sidewall of the third conductive connection member.

In example embodiments, when the molding member is formed on the RDL to cover the at least a portion of the sidewall of the first semiconductor chip and the sidewall of the conductive post, the molding member may be formed on the RDL to cover the first semiconductor chip and the conductive post. An upper portion of the molding member may be removed by a grinding process.

In example embodiments, when the upper package is mounted to contact the upper surface of the heat dissipation member, a first bonding layer including a first bonding pattern may be formed on the molding member, the heat dissipation member and the conductive post. A second bonding layer including a second bonding pattern may be formed on a lower surface of the upper package. The first and second bonding layers may be bonded such that the first and second bonding patterns may contact each other. The first bonding pattern may contact an upper surface of the conductive post.

In the semiconductor package in accordance with some embodiments, an upper portion of the semiconductor chip on the RDL may not be covered by the molding member having a lower heat dissipation effect and may contact the heat dissipation member having a high heat dissipation effect. Thus, the heat generated from the semiconductor chip may be efficiently dissipated through the heat dissipation member and the package substrate, so that the semiconductor package may have enhanced heat dissipation characteristics.

### BRIEF DESCRIPTION OF THE DRAWINGS

FIG. 1 is a cross-sectional view illustrating a semiconductor package in accordance with some embodiments.

FIGS. 2 to 7 are cross-sectional views illustrating a method of manufacturing a semiconductor package in accordance with some embodiments.

FIG. 8 is a cross-sectional view illustrating a semiconductor package in accordance with some embodiments.

FIG. 9 is a cross-sectional view illustrating a semiconductor package in accordance with some embodiments.

FIG. 10 is a cross-sectional view illustrating a method of manufacturing a semiconductor package in accordance with some embodiments.

FIG. 11 is a semiconductor package in accordance with some embodiments.

FIG. 12 is a cross-sectional view illustrating a semiconductor package in accordance with some embodiments.

FIGS. 13 and 14 are cross-sectional views illustrating a method of manufacturing a semiconductor package in accordance with some embodiments.

### DETAILED DESCRIPTION

Hereinafter, some embodiments will be explained in detail with reference to the accompanying drawings. It will be understood that, although the terms “first,” “second,” and/or “third” may be used herein to describe various materials, layers (films), regions, electrodes, pads, patterns, structures and processes, these materials, layers (films), regions, electrodes, pads, patterns, structures and processes should not be limited by these terms. These terms are only used to distinguish one material, layer (film), region, electrode, pad, pattern, structure and process from another material, layer (film), region, electrode, pad, pattern, structure and process. Thus, a first material, layer (film), region, electrode, pad, pattern, structure and process discussed below could be termed a second or third material, layer (film), region, electrode, pad, pattern, structure and process without departing from the teachings of inventive concepts.

The terms “comprises,” “comprising,” “includes,” and/or “including,” when used herein, specify the presence of stated elements, but do not preclude the presence of additional elements. The term “and/or” includes any and all combinations of one or more of the associated listed items.

The term “connected” may be used herein to refer to a physical and/or electrical connection.

Further, spatially relative terms, such as “under,” “below,” “lower,” “over,” “upper,” etc., may be used herein for ease of description to describe one element or relationship of structures to another element or structure as illustrated in the drawings.

A first element described as “on” a second element may be disposed directly on the second element (e.g., in contact with the second element) or indirectly on the second element (e.g., with an intervening element interposed between the first and second elements). When components or layers are referred to herein as “directly” on, “in contact with,” “contacting,” “engaged with,” “engaging,” or “directly connected,” no intervening components or layers are present.

Components or layers described with reference to “overlap” in a particular direction are at least partially obstructed by one another when viewed along a line extending in the particular direction or in a plane perpendicular to the particular direction. As used herein, “an element A overlapping an element B in a direction C” (or similar language) means that there is at least one line that extends in the direction C that intersects both the element A and the element B. For example, the element B may be a layer that is stacked or superimposed over (i.e., on top of) the element A, in which case the layer B may be described as overlapping the element A in a vertical direction. However, it will be appreciated that the direction C is not limited to the vertical direction and may be, for example, a horizontal direction or any direction between vertical and horizontal.

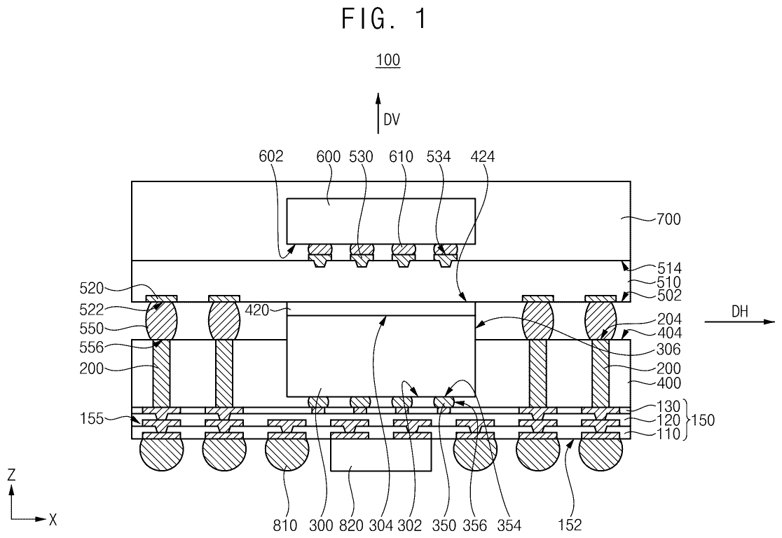

FIG. 1 is a cross-sectional view illustrating a semiconductor package 100 in accordance with some embodiments.

Referring to FIG. 1, the semiconductor package 100 may include a first semiconductor chip 300, a heat dissipation member 420, a conductive post 200, a first molding member 400, a package substrate 510, a second semiconductor chip 600 and a second molding member 700 on a redistribution layer (RDL) 150.

The semiconductor package 100 may further include first, second, fifth and sixth conductive connection members 810, 350, 610, and 550 and a third semiconductor chip 820.

As shown in FIG. 1, components of the semiconductor package 100 are stacked along a vertical direction DV, which is parallel to a vertical or Z-axis. As discussed herein, certain components or features of the semiconductor package 100 are relatively arranged (and in some cases spaced apart) along a horizontal direction DH, which is parallel to a horizontal or X-axis. The X-axis may be perpendicular to the Z-axis, and the horizontal direction DH may be perpendicular to the vertical direction DV.

The RDL 150 may include insulation layers stacked in the vertical direction DV and a redistribution wiring structure 155 in the insulation layers, and the redistribution wiring structure 155 may include, e.g., redistribution wirings, vias, contact plugs, conductive pads, etc.

FIG. 1 shows that the RDL 150 includes first, second and third insulation layers 110, 120, and 130 sequentially stacked in the vertical direction DV, and the redistribution wiring structure 155 is formed in the first, second and third insulation layers 110, 120, and 130. However, the inventive concept is not limited thereto, and the RDL 150 may include less than or more than three insulation layers sequentially stacked in the vertical direction DV.

Each of the redistribution wirings, vias, contact plugs, conductive pads, etc., included in the redistribution wiring structure 155 may have various types of layouts in the insulation layers.

Each of the first to third insulation layers 110, 120, and 130 may include an organic material, e.g., photo imageable dielectric (PID). The organic material may include, e.g., polyimide, polybenzoxazole, etc. The redistribution wirings, the vias, the contact plugs, the conductive pads, etc., included in the redistribution wiring structure 155 may include a conductive material, e.g., a metal, a metal nitride, a metal silicide, etc.

The first conductive connection member 810 may be disposed on a lower surface 152 of the RDL 150 and may contact or engage a portion of the redistribution wiring structure 155, e.g., a conductive pad. In some embodiments, a plurality of first conductive connection members 810 may be spaced apart from each other in a horizontal direction DH, and may be on and electrically connected to a package substrate, e.g., a printed circuit board (PCB), a mother board, etc.

The first conductive connection member 810 may be, e.g., a conductive bump or a conductive ball, and may include, e.g., solder that is an alloy of, e.g., tin, silver, copper, etc., or a metal such as copper, aluminum, nickel, etc.

The first semiconductor chip 300 may be on the RDL 150 via or with the second conductive connection member 350 disposed therebetween, and thus may be electrically connected to the redistribution wiring structure 155. The first semiconductor chip 300 may include first and second surfaces opposite to each other in the vertical direction DV. The first surface of the first semiconductor chip 300 may be a lower surface 302, may face downwardly in the vertical direction DV, and may contact or engage an upper surface 354 of the second conductive connection member 350. In other words, the first surface of the first semiconductor chip 300 may be a lower surface 302 of the first semiconductor chip 300 and the second surface of the first semiconductor chip 300 may be an upper surface 304 of the first semiconductor chip 300.

The first semiconductor chip 300 may be a logic chip including a controller, e.g., application processor (AP). Alternatively, the first semiconductor chip 300 may be a memory chip including a volatile memory device such as a DRAM device, an SRAM device, etc., or a non-volatile memory device such as a flash memory device, an EEPROM device, etc.

The first molding member 400 may be disposed on the RDL 150 and may cover at least a lower portion of the sidewall 306 of the first semiconductor chip 300, a first or lower surface 302 of the first semiconductor chip 300, and a sidewall 356 of the second conductive connection member 350. The first molding layer or member 400 may include, e.g., epoxy molding compound (EMC).

The conductive post 200 may extend through the first molding member 400 in the vertical direction DV and may contact or engage a portion of the redistribution wiring structure 155 to be electrically connected thereto. In some embodiments, a plurality of conductive posts 200 may be spaced apart from each other in the horizontal direction DH and may surround the first semiconductor chip 300 in a plan view.

In some embodiments, an upper surface 204 of the conductive post 200 may be substantially coplanar with an upper surface 404 of the first molding member 400, and the upper surfaces 204, 404 of the conductive post 200 and the first molding member 400 may be lower in the vertical direction DV than the second or upper surface 304 of the first semiconductor chip 300.

The conductive post 200 may include a metal, e.g., copper, aluminum, etc.

The heat dissipation member 420 may contact or engage the second or upper surface 304 of the first semiconductor chip 300, and may include, e.g., thermal interface material (TIM).

The package substrate 510 may be, e.g., a printed circuit board (PCB), however, the inventive concept is not limited thereto. The package substrate 510 may include first and second surfaces opposite to each other in the vertical direction DV The first surface of the package substrate 510 may be a lower surface 512 and may contact or engage an upper surface 424 of the heat dissipation member 420. In other words, the first surface of the package substrate 510 may be a lower surface 512 of the package substrate 510 and the second surface of the package substrate 510 may be an upper surface 514 of the package substrate 510.

A first conductive pad 520 may be disposed at a portion of the package substrate 510 adjacent to the first or lower surface 512 thereof, and a second conductive pad 530 may be disposed on the second or upper surface 514 thereof. In other words, a first conductive pad 520 may be on or in the package substrate 510 and may be adjacent to the first or lower surface 512 of the package substrate 510. The first conductive pad 520 may be considered a part of the package substrate 510 and, therefore, the first or lower surface 512 of the package substrate 510 may include the lower surface 522 of the first conductive pad 520. Similarly, the second conductive pad 530 may be on or in the package substrate 510 and may be adjacent to the second or upper surface 514 of the package substrate 510. The second conductive pad 530 may be considered a part of the package substrate 510 and, therefore, the second or upper surface 514 of the package substrate 510 may include the upper surface 534 of the second conductive pad 530. Each of the first and second conductive pads 520 and 530 may include, e.g., aluminum, copper, tin, nickel, gold, platinum, or an alloy thereof.

The sixth conductive connection member 550 may be disposed between and in contact with or engaged to the upper surface 204 of the conductive post 200 and a lower surface 522 of the first conductive pad 520. In some embodiments, a lower surface 552 of the sixth conductive connection member 550 may be lower, in the vertical direction DV, than a first or lower surface 302 of the first semiconductor chip 300. The sixth conductive connection member 550 may include, e.g., a conductive bump or a conductive ball, which may include, e.g., solder.

The second semiconductor chip 600 may be electrically connected to the second conductive pad 530 on the second or upper surface 514 of the package substrate 510 via the fifth conductive connection member 610. The second semiconductor chip 600 may include a volatile memory device such as a DRAM device, an SRAM device, etc., or a non-volatile memory device such as a flash memory device, an EEPROM device, etc., however, the inventive concept is not limited thereto.

The fifth conductive connection member 610 may contact or engage an upper surface 534 of the second conductive pad 530 and a lower surface 602 of the second semiconductor chip 600. The fifth conductive connection member 610 may include, e.g., a conductive bump or a conductive ball, which may include, e.g., solder.

The second molding member 700 may be disposed on the second or upper surface 514 of the package substrate 510, and may cover the second semiconductor chip 600, the fifth conductive connection member 610 and the second conductive pad 530. The second molding member 700 may include, e.g., EMC.

The third semiconductor chip 820 may be disposed beneath the RDL 150 and may contact or engage a portion of the redistribution wiring structure 155. In some embodiments, the third semiconductor chip 820 may be a dummy chip and may serve as a bridge for electrical connection between the redistribution wiring structures 155. Alternatively, the third semiconductor chip 820 may be, e.g., a memory chip, a logic chip, etc.

In some embodiments, a thickness in the vertical direction DV of the first semiconductor chip 300 may be greater than an extension length in the vertical direction DV of the conductive post 200, and a second or upper surface 304 of the first semiconductor chip 300 may be higher, in the vertical direction DV, than the upper surface 404 of the first molding member 400, which may be substantially coplanar with the upper surface 204 of the conductive post 200. In other words, the upper surface 204 of the conductive post 200 and the upper surface 404 of the first molding member 400 may be substantially coplanar and the second or upper surface 304 of the first semiconductor chip 300 may be higher, in the vertical direction DV, than both the upper surface 204 of the conductive post 200 and the upper surface 404 of the first molding member 400.

Thus, an upper portion of the first semiconductor chip 300 may not be covered by the first molding member 400 having a low heat dissipation effect and may contact or engage the heat dissipation member 420 having a high heat dissipation effect. In other words, an upper portion of the sidewall 306 of the first semiconductor chip 300 may not be covered by the first molding member 400. Additionally, the second or upper surface 304 of the first semiconductor chip 300 may contact or engage the heat dissipation member 420 and may therefore have a high heat dissipation effect. As a result, heat generated by the first semiconductor chip 300 may be efficiently dissipated through the heat dissipation member 420 and the package substrate 510 in contact with the heat dissipation member 420, and thus the semiconductor package 100 may have enhanced heat dissipation characteristics.

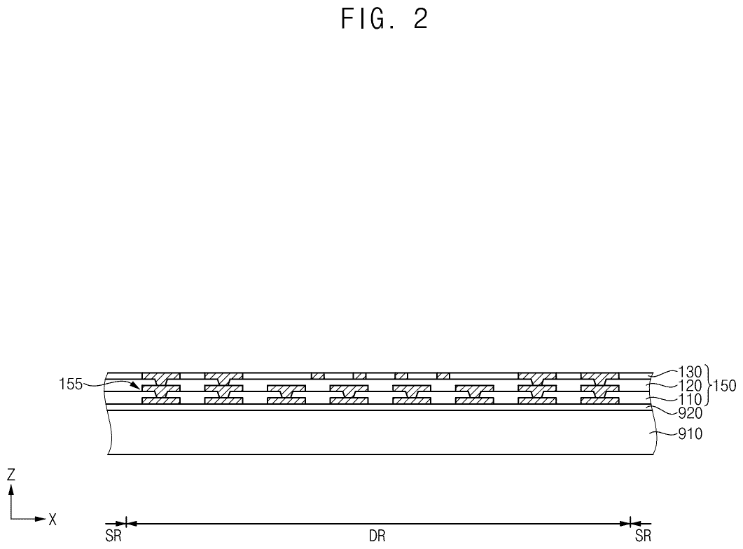

FIGS. 2 to 7 are cross-sectional views illustrating a method of manufacturing a semiconductor package 100 in accordance with some embodiments.

Referring to FIG. 2, a temporary adhesion layer 920 may be attached to a carrier wafer 910, and an RDL 150 may be formed on the temporary adhesion layer 920.

The carrier wafer 910 may include, e.g., a non-metallic or metallic plate, a silicon substrate, a glass substrate, etc. The carrier wafer 910 may include a plurality of die regions DR and a scribe lane region SR surrounding the die regions DR.

The temporary adhesion layer 920 may include a material having adhesion by irradiating light or heating, or a release tape.

In some embodiments, the RDL 150 may include insulation layers sequentially stacked in the vertical direction DV and a redistribution wiring structure 155 therein, and the redistribution wiring structure 155 may include, e.g., redistribution wirings, via, contact plugs, conductive pads, etc.

FIG. 2 shows that the RDL 150 includes first to third insulation layers 110, 120, and 130 sequentially stacked in the vertical direction DV, and the redistribution wiring structure 155 is formed in the first to third insulation layers 110, 120, and 130.

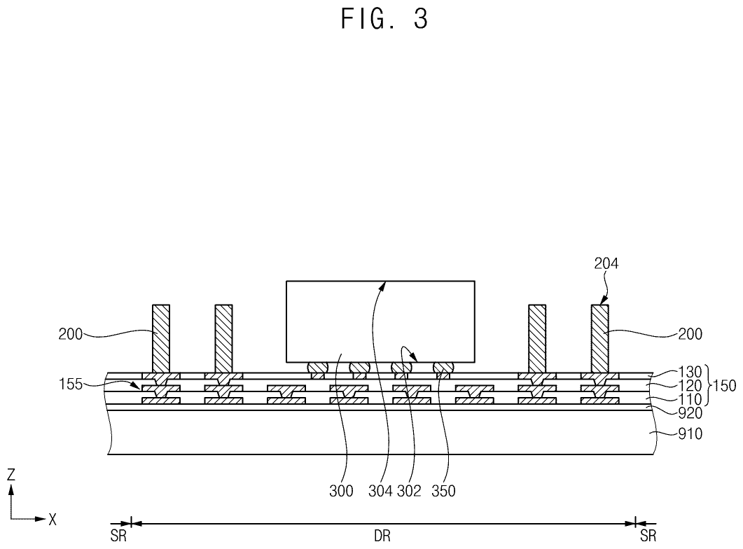

Referring to FIG. 3, a conductive post 200 may be formed to contact or engage a portion of the redistribution wiring structure 155, and a first semiconductor chip 300 may be electrically connected to a portion of the redistribution wiring structure 155.

In some embodiments, the conductive post 200 may be formed by forming a photoresist layer on the RDL 150, forming an opening to expose the portion of the redistribution wiring structure 155, and performing, e.g., an electroplating process so as to be formed in the opening.

The photoresist layer may be removed by, e.g., an ashing process and/or a stripping process.

The first semiconductor chip 300 may be electrically connected to the portion of the redistribution wiring structure 155 through a second conductive connection member 350. The second conductive connection member 350 may include, e.g., a conductive bump or a conductive ball, which may include, e.g., solder that is an alloy of tin, silver, copper, lead, etc.

The first semiconductor chip 300 may include first and second surfaces opposite to each other in the vertical direction DV which may be a lower surface 302 and an upper surface 304, respectively. The first or lower surface 302 of the first semiconductor chip 300 may face downwardly in the vertical direction DV when the first semiconductor chip 300 is mounted.

In some embodiments, a plurality of conductive posts 200 may be spaced apart from each other in the horizontal direction DH and may surround the first semiconductor chip 300 in a plan view.

In some embodiments, the second or upper surface 304 of the first semiconductor chip 300 may be higher than an upper surface 204 of the conductive post 200.

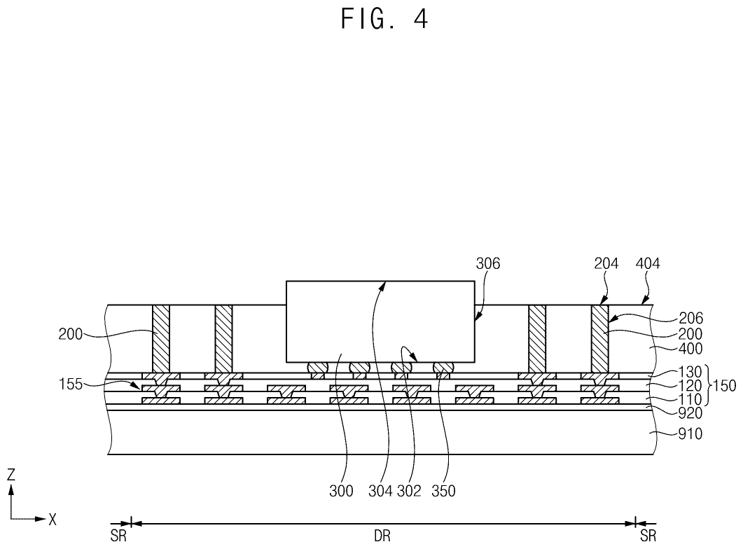

Referring to FIG. 4, a first molding member 400 may be formed on the RDL 150.

The first molding member 400 may cover at least a lower portion of the sidewall 306 of the first semiconductor chip 300, a first or lower surface 302 of the first semiconductor chip 300, a sidewall 356 of the second conductive connection member 350, and a sidewall 206 of the conductive post 200. Additionally, an upper surface 404 of the first molding member 400 may be substantially coplanar with the upper surface 204 of the conductive post 200. Thus, the upper surface 404 of the first molding member 400 may be lower than the second or upper surface 304 of the first semiconductor chip 300.

In some embodiments, a mask may be formed to cover the second or upper surface 304 of the first semiconductor chip 300, the first molding member 400 may be formed on the RDL 150 to have the upper surface 404 substantially coplanar with the upper surface 204 of the conductive post 200, and the mask may be removed so that the first molding member 400 may cover at least a lower portion of the sidewall 306 of the first semiconductor chip 300, the lower surface 302 of the first semiconductor chip 300, the sidewall 356 of the second conductive connection member 350, and the sidewall 206 of the conductive post 200.

Alternatively, the first molding member 400 may be formed on the RDL 150 to cover the first semiconductor chip 300, the second conductive connection member 350 and the conductive post 200, and an upper portion of the first molding member 400 may be removed by, e.g., a grinding process until the upper surface 204 of the conductive post 200 is exposed so that the first molding member 400 may cover at least a lower portion of the sidewall 306 of the first semiconductor chip 300, the lower surface 302 of the first semiconductor chip 300, the sidewall 356 of the second conductive connection member 350, and the sidewall 206 of the conductive post 200.

The first molding member 400 may include, e.g., epoxy molding compound (EMC).

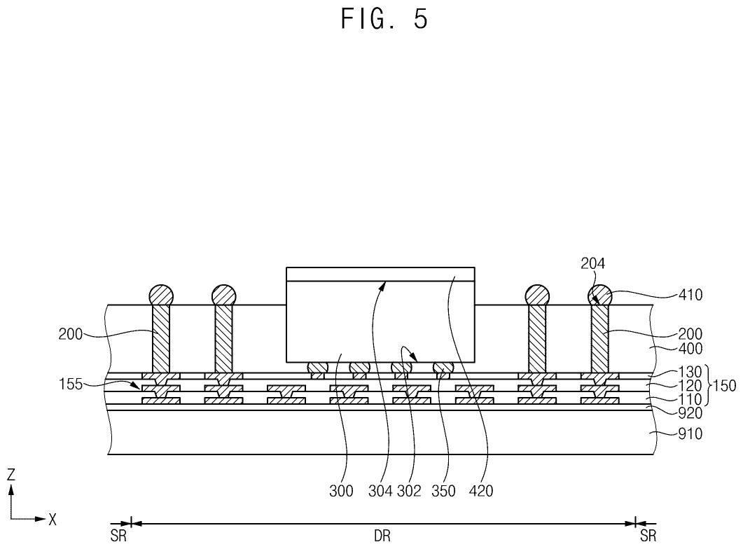

Referring to FIG. 5, a third conductive connection member 410 may be formed on the upper surface 204 of the conductive post 200, and a heat dissipation member 420 may be formed on the second or upper surface 304 of the first semiconductor chip 300.

The third conductive connection member 410 may include, e.g., a conductive bump or a conductive ball, which may include, e.g., solder.

The heat dissipation member 420 may include, e.g., TIM.

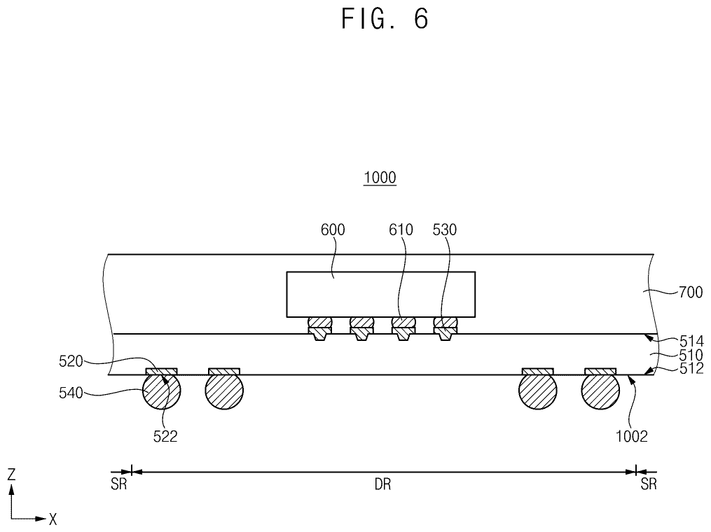

Referring to FIG. 6, an upper package 1000 may be provided.

In some embodiments, the upper package 1000 may include a package substrate 510, a second semiconductor chip 600, and a second molding member 700.

The package substrate 510 may be, e.g., a PCB, however, the inventive concept is not limited thereto. The package substrate 510 may include first and second surfaces opposite to each other in the vertical direction DV which may be a lower surface 512 and an upper surface 514, respectively. The package substrate 510 may include a plurality of die regions DR and a scribe lane region SR surrounding the die regions DR.

A first conductive pad 520 may be formed at a portion of the package substrate 510 adjacent to the first or lower surface 512, and a second conductive pad 530 may be formed on the second or upper surface 514 of the package substrate 510.

A fourth conductive connection member 540 may be formed on and contact or engage the lower surface 522 of the first conductive pad 520. In some embodiments, the fourth conductive connection member 540 may include a material substantially the same as a material of the third conductive connection member 410. Thus, the fourth conductive connection member 540 may include, e.g., a conductive bump or a conductive ball, which may include, e.g., solder.

The second semiconductor chip 600 may be electrically connected to the second conductive pad 530 on the second or upper surface 514 of the package substrate 510 through a fifth conductive connection member 610.

The second molding member 700 may be formed on the second or upper surface 514 of the package substrate 510, and may cover the second semiconductor chip 600, the fifth conductive connection member 610, and the second conductive pad 530.

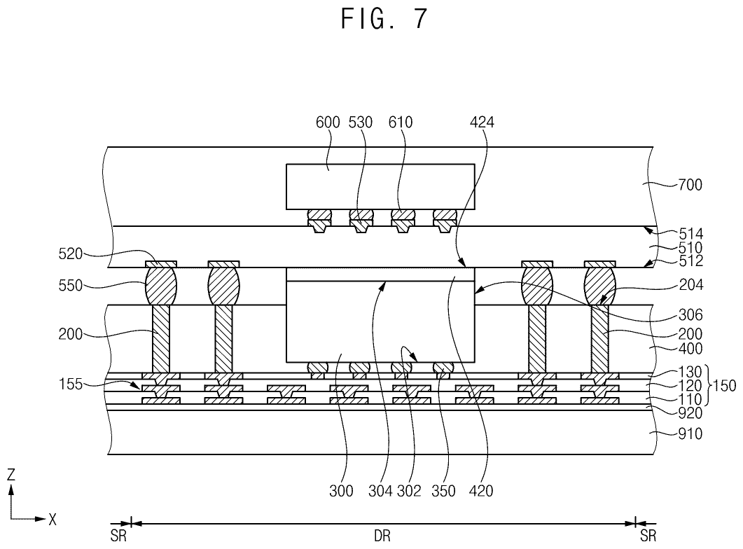

Referring to FIG. 7, the upper package 1000 may be on the heat dissipation member 420 such that the die regions DR of the package substrate 510 may overlap the die regions DR, respectively, of the carrier wafer 910 in the vertical direction DV, and the fourth conductive connection members 540 may contact or engage the third conductive connection members 410, respectively.

A reflow process may be performed on the third and fourth conductive connection members 410 and 540 so that the third and fourth conductive connection members 410 and 540 having substantially the same material may be merged with each other to form a sixth conductive connection member 550. The first or lower surface 512 of the package substrate 510 included in the upper package 1000 may contact or engage an upper surface 424 of the heat dissipation member 420.

The carrier wafer 910 may be flipped and may be attached to an upper surface of a dicing film on a ring frame, and the dicing film may contact or engage an upper surface of the second molding member 700.

For example, a sawing process may be performed along the scribe lane region SR to cut the carrier wafer 910 so as to be singulated into a plurality of carrier substrates.

During the sawing process, the temporary adhesion layer 920, the RDL 150, the first molding member 400, the package substrate 510 and the second molding member 700 under the carrier wafer 910 may also be cut to be stacked under each of the singulated carrier substrate.

The carrier substrate and the temporary adhesion layer 920 may be separated from the RDL 150, and a first conductive connection member 810 in contact with or engaged to a portion of the redistribution wiring structure 155 and a third semiconductor chip 820 electrically connected to a portion of the redistribution wiring structure 155 may be mounted.

Alternatively, after separating the carrier wafer 910 and the temporary adhesion layer 920 from the RDL 150, the sawing process may be performed. After the sawing process, the first conductive connection member 810 in contact with or engaged to the portion of the redistribution wiring structure 155 and the third semiconductor chip 820 electrically connected to the portion of the redistribution wiring structure 155 may be mounted.

The second molding member 700 may be separated from the dicing film to complete the manufacturing of the semiconductor package 100.

As illustrated above, the first semiconductor chip 300 having a high thickness in the vertical direction DV may be formed on the RDL 150 so that the second or upper surface 304 of the first semiconductor chip 300 may be higher than the upper surface 204 of the conductive post 200. The third conductive connection member 410 may be formed on the conductive post 200, the heat dissipation member 420 may be formed on the first semiconductor chip 300, the first or lower surface 512 of the package substrate 510 in the upper package 1000 may contact or engage the upper surface 424 of the heat dissipation member 420, and the fourth conductive connection member 540 in the upper package 1000 may contact or engage the third conductive connection member 410 on the conductive post 200. The third and fourth conductive connection members 410 and 540 may be merged with each other through a reflow process to form the sixth conductive connection member 550.

Thus, an upper portion of the first semiconductor chip 300 may not be covered by the first molding member 400 having a low heat dissipation effect, and the upper surface 304 of the first semiconductor chip 300 may contact or engage the heat dissipation member 420 having a high heat dissipation effect. In other words, an upper portion of the sidewall 306 of the first semiconductor chip 300 may not be covered by the first molding member 400. Additionally, the upper surface 304 of the first semiconductor chip 300 may contact or engage the heat dissipation member 420 and may therefore experience a high heat dissipation effect. As a result, heat generated by the first semiconductor chip 300 may be efficiently dissipated through the heat dissipation member 420 and the package substrate 510 in contact with or engaged to the heat dissipation member 420, thus the semiconductor package 100 may have enhanced heat dissipation characteristics.

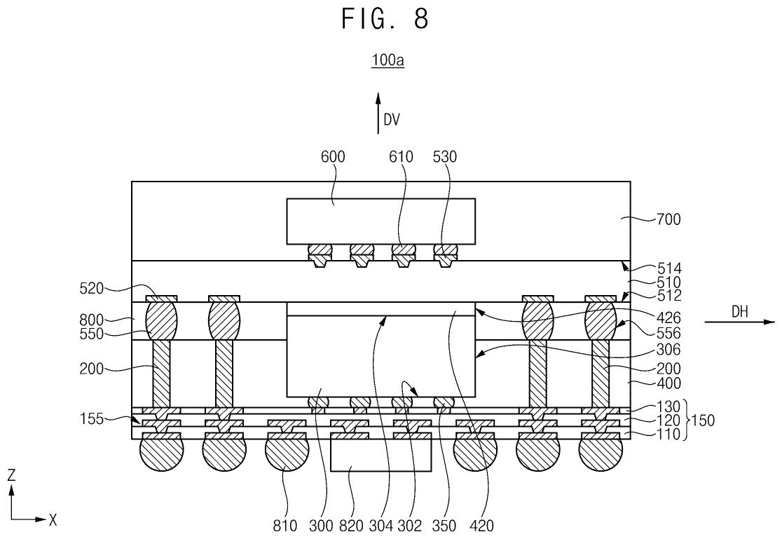

FIG. 8 is a cross-sectional view illustrating a semiconductor package 100a in accordance with some embodiments.

In some embodiments, the semiconductor package 100a may be substantially the same as or similar to that of FIG. 1, except for an underfill member 800, and repeated explanations are omitted herein.

Referring to FIG. 8, the semiconductor package 100a may further include an underfill member 800 that may be disposed between the first molding member 400 and the package substrate 510 and may cover at least an upper portion of the sidewall 306 of the first semiconductor chip 300, the sidewall 426 of the heat dissipation member 420, and/or the sidewall 556 of the sixth conductive connection member 550.

The underfill member 800 may include an adhesive that may include, e.g., epoxy.

The semiconductor package 100a may be manufactured by performing the processes illustrated with reference to FIGS. 2 to 7, performing a reflow process to form the sixth conductive connection member 550, and filling an underfill material into a space between the first molding member 400 and the package substrate 510. In other words, after forming the sixth conductive connection member 550, an underfill member 800 may be formed between the first molding member 400 and the package substrate 510 to cover a sidewall 556 of the sixth conductive connection member 550.

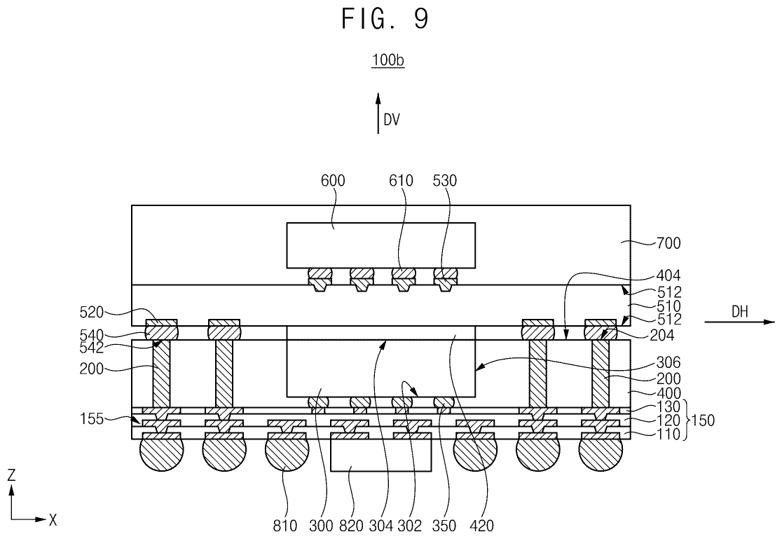

FIG. 9 is a cross-sectional view illustrating a semiconductor package 100b in accordance with some embodiments.

In some embodiments, the semiconductor package 100b may be substantially the same as or similar to that of FIG. 1, except for some elements, and repeated explanations are omitted herein.

Referring to FIG. 9, the second or upper surface 304 of the first semiconductor chip 300 may be substantially coplanar with the upper surface 204 of the conductive post 200 and the upper surface 404 of the first molding member 400, and thus the sidewall 306 of the first semiconductor chip 300 may be entirely covered by the first molding member 400.

However, the heat dissipation member 420 may be disposed on the second or upper surface 304 of the first semiconductor chip 300, and thus heat generated from the first semiconductor chip 300 may be dissipated through the heat dissipation member 420 and the package substrate 510.

The fourth conductive connection member 540, instead of the sixth conductive connection member 550, may be disposed between the conductive post 200 and the first conductive pad 520 on the package substrate 510.

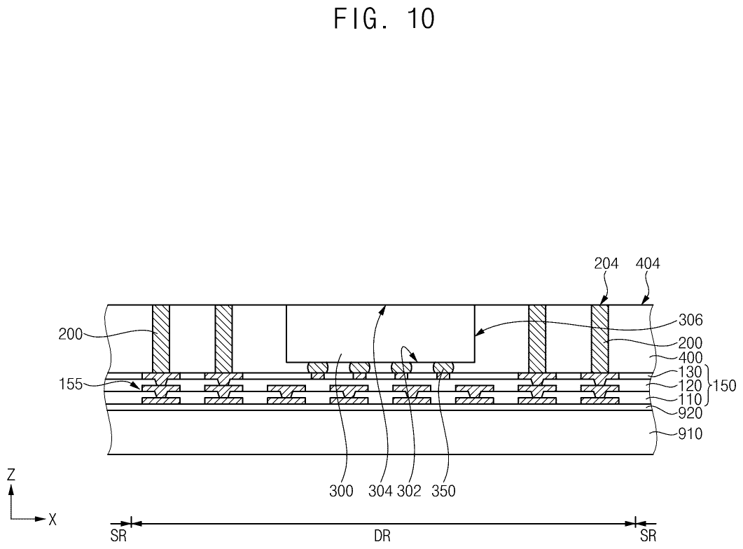

FIG. 10 is a cross-sectional view illustrating a method of manufacturing a semiconductor package 100b in accordance with some embodiments.

In some embodiments, the method of manufacturing semiconductor package 100b may include processes substantially the same as or similar to those of FIGS. 2 to 7 and FIG. 1, and repeated explanations thereof are omitted herein.

Referring to FIG. 10, processes substantially the same as or similar to those illustrated with respect to FIGS. 2 to 4 may be performed.

However, the second or upper surface 304 of the first semiconductor chip 300 may be substantially coplanar with the upper surface 204 of the conductive post 200, and thus the sidewall 306 of the first semiconductor chip 300 may be entirely covered by the first molding member 400.

Unlike the processes illustrated with reference to of FIG. 5, the third conductive connection member 410 may not be formed on the upper surface 204 of the conductive post 200, the heat dissipation member 420 may be formed on the second or upper surface 304 of the first semiconductor chip 300.

Processes substantially the same as or similar to those illustrated with respect to FIGS. 6 and 7 and FIG. 1 may be performed to manufacture the semiconductor package 100b shown in FIG. 9. However, the third conductive connection member 410 may not be formed on the upper surface 204 of the conductive post 200, and thus the fourth conductive connection member 540 may contact or engage the upper surface 204 of the conductive post 200.

In some embodiments, a lower surface 542 of the fourth conductive connection member 540 may be substantially coplanar with the second or upper surface 304 of the first semiconductor chip 300.

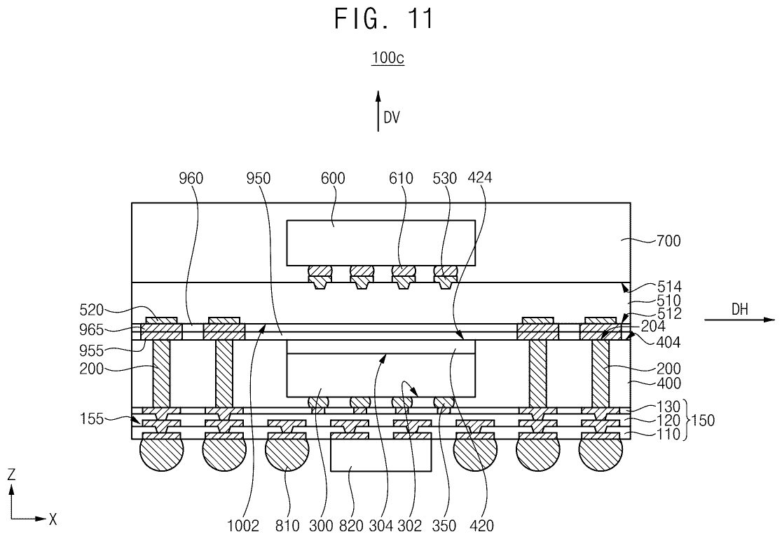

FIG. 11 is a semiconductor package 100c in accordance with some embodiments.

In some embodiments, the semiconductor package 100c may be substantially the same as or similar to that of FIG. 1, except for an underfill member 800, and repeated explanations are omitted herein.

Referring to FIG. 11, the second or upper surface 304 of the first semiconductor chip 300 may be lower than the upper surfaces 204, 404 of the conductive post 200 and the first molding member 400. In some embodiments, an upper surface 424 of the heat dissipation member 420 may be substantially coplanar with the upper surfaces 204, 404 of the conductive post 200 and the first molding member 400.

A bonding layer structure including first and second bonding layers 950 and 960, instead of the sixth conductive connection member 550, may be disposed between the first or lower surface 512 of the package substrate 510 and the upper surfaces 404, 424, 204 of the first molding member 400, the heat dissipation member 420, and/or the conductive post 200. The first and second bonding patterns 955 and 965 may be in the first and second bonding layers 950 and 960, respectively. In other words, the first and second bonding layers 950, 960 may include first and second bonding patterns 955, 965, respectively. The first and second bonding patterns 955 and 965 may contact or engage each other to form a bonding pattern structure, which may contact or engage the upper surface 204 of the conductive post 200 to be electrically connected thereto.

In some embodiments, each of the first and second bonding layers 950 and 960 may include, e.g., silicon carbonitride, silicon oxide, and each of the first and second bonding patterns 955 and 965 may include, e.g., copper.

The semiconductor package 100 may be manufactured by a hybrid copper bonding (HCB) process in which the first molding member 400, the heat dissipation member 420, and the conductive post 200 are bonded with the upper package 1000.

In other words, in some embodiments, the semiconductor package 100 may be manufactured by performing the processes illustrated with reference to FIGS. 2 to 7, wherein mounting the upper package 1000 to contact or engage the upper surface 424 of the heat dissipation member 420 includes: (a) forming the first bonding layer 950 including a first bonding pattern 955 on the first molding member 400, the heat dissipation member 420, and the conductive post 200; (b) forming a second bonding layer 960 including a second bonding pattern 965 on a lower surface 1002 of the upper package 1000; and (c) bonding the first and second bonding layers 950, 960 such that the first and second bonding patterns 955, 965 contact or engage each other, wherein the first bonding pattern 955 contacts or engages an upper surface 204 of the conductive post 200.

In the semiconductor package 100, the heat dissipation member 420 on the second or upper surface 304 of the first semiconductor chip 300 may be connected to the package substrate 510 through the first and second bonding layers 950 and 960, and the first and second bonding layers 950 and 960 may have a dissipation effect greater than that of the first molding member 400 including, e.g., EMC, so that the semiconductor package 100 may have enhanced heat dissipation characteristics.

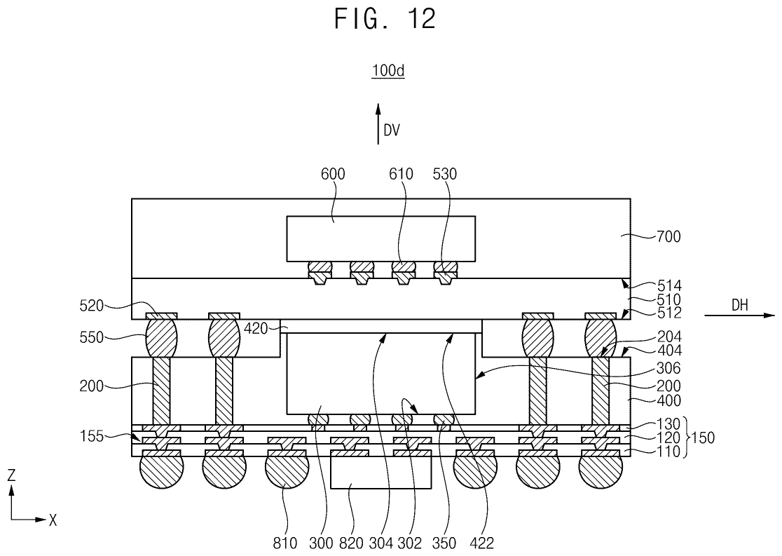

FIG. 12 is a cross-sectional view illustrating a semiconductor package 100d in accordance with some embodiments. The semiconductor package 100d may be substantially the same as or similar to that of FIG. 1, except for the first molding member 400, and thus repeated explanations are omitted herein.

Referring to FIG. 12, a portion of the first molding member 400 may be on at least an upper portion of the sidewall 306 of the first semiconductor chip 300 higher than the upper surface 204 of the conductive post 200. In some embodiments, an edge portion of the heat dissipation member 420 may be on and in contact with or engaged to the portion of the first molding member 400.

In some embodiments, at least a portion of the heat dissipation member 420 may contact or engage and overlap in the vertical direction DV the first molding member 400. In other words, a first portion of the upper surface 404 of the first molding member 400 may be lower in the vertical direction DV than a second portion of the upper surface 404 of the first molding member 400. The second portion of the upper surface 404 of the first molding member 400 may contact or engage at least a portion of the heat dissipation member 420 which may be a portion of the lower surface 422 of the heat dissipation member 420.

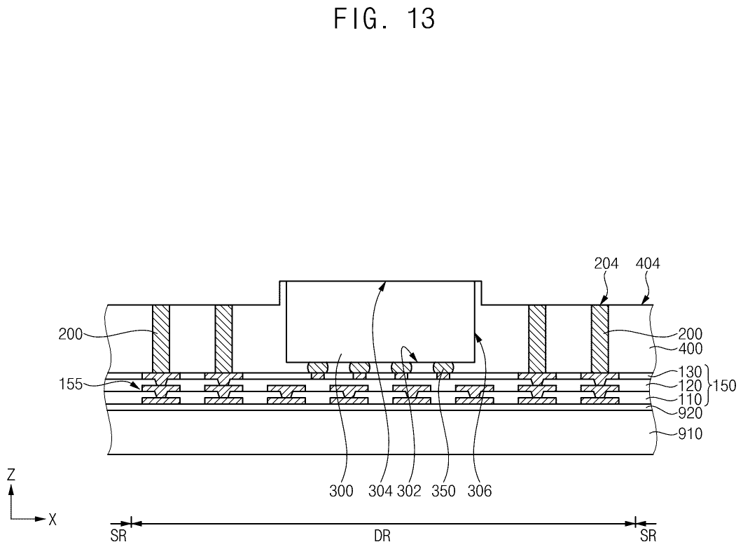

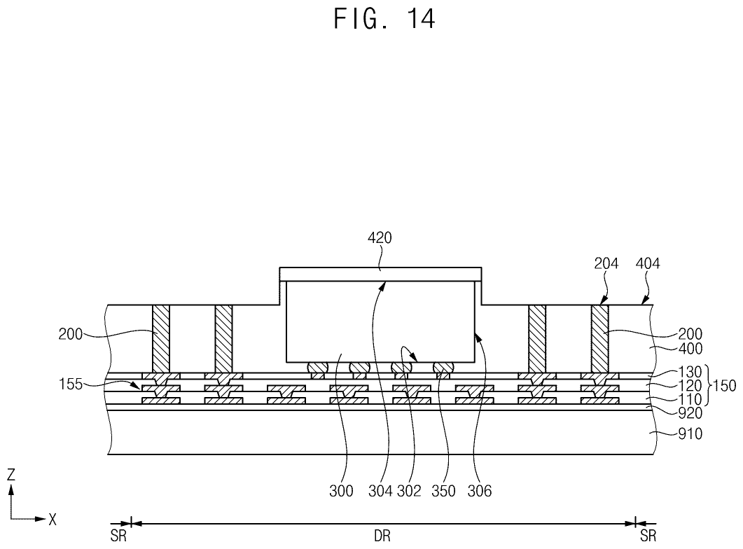

FIGS. 13 and 14 are cross-sectional views illustrating a method of manufacturing a semiconductor package 100d in accordance with some embodiments. The method may include processes substantially the same as or similar to those illustrated with respect to FIGS. 2 to 7 and FIG. 1, and thus repeated explanations thereof are omitted herein.

Referring to FIG. 13, processes substantially the same as or similar to those illustrated with respect to FIGS. 2 to 4 may be performed.

However, during the formation of the first molding member 400, the first molding member 400 may remain on a portion of the sidewall 306 of the first semiconductor chip 300 higher than the upper surface 204 of the conductive post 200.

Referring to FIG. 14, processes substantially the same as or similar to those illustrated with respect to FIG. 5 may be performed.

However, the heat dissipation member 420 may be formed not only on the second or upper surface 304 of the first semiconductor chip 300 but also on an upper surface 404 of the first molding member 400 remaining on the sidewall 306 of the first semiconductor chip 300.

Referring back to FIG. 12, processes substantially the same as or similar to those illustrated with respect to FIGS. 6 and 7 and FIG. 1 may be performed to complete the manufacturing of the semiconductor package 100d.

The foregoing is illustrative of some embodiments and is not to be construed as limiting thereof. Although a few some embodiments have been described, those skilled in the art will readily appreciate that many modifications are possible in some embodiments without materially departing from the novel teachings and advantages of the present invention. Accordingly, all such modifications are intended to be included within the scope of some embodiments as defined in the claims.

What is claimed is:

1. A semiconductor package comprising:
a redistribution layer (RDL) including a redistribution wiring structure;
a first semiconductor chip on the RDL and electrically connected to the redistribution wiring structure;
a heat dissipation member in contact with an upper surface of the first semiconductor chip;
a conductive post on the RDL and spaced apart from the first semiconductor chip in a horizontal direction, wherein the conductive post is electrically connected to the redistribution wiring structure;
a first molding member on the RDL and configured to cover at least a portion of a sidewall of the first semiconductor chip and a sidewall of the conductive post;
a package substrate in contact with an upper surface of the heat dissipation member and electrically connected to the conductive post;
a second semiconductor chip on and electrically connected to the package substrate; and
a second molding member on the package substrate and configured to cover the second semiconductor chip.

2. The semiconductor package according to claim 1, wherein an upper surface of the first molding member is lower, in a vertical direction, than the upper surface of the first semiconductor chip.

3. The semiconductor package according to claim 2, further comprising a conductive connection member in contact with an upper surface of the conductive post and a lower surface of the package substrate.

4. The semiconductor package according to claim 3, wherein a lower surface of the conductive connection member is lower, in the vertical direction, than the upper surface of the first semiconductor chip.

5. The semiconductor package according to claim 2, further comprising an underfill member between the upper surface of the first molding member and a lower surface of the package substrate, the underfill member configured to cover a sidewall of a conductive connection member and a sidewall of the heat dissipation member.

6. The semiconductor package according to claim 1, wherein an upper surface of the first molding member is substantially coplanar with the upper surface of the first semiconductor chip.

7. The semiconductor package according to claim 6, further comprising a conductive connection member in contact with an upper surface of the conductive post and a lower surface of the package substrate.

8. The semiconductor package according to claim 7, wherein a lower surface of the conductive connection member is substantially coplanar with the upper surface of the first semiconductor chip.

9. The semiconductor package according to claim 1, wherein an upper surface of the first molding member is substantially coplanar with the upper surface of the heat dissipation member.

10. The semiconductor package according to claim 9, further comprising:
a bonding layer structure between the upper surface of the first molding member and a lower surface of the package substrate; and
the bonding layer structure including a bonding pattern structure in the bonding layer structure, the bonding pattern structure in contact with the upper surface of the conductive post.

11. The semiconductor package according to claim 1, wherein a portion of the heat dissipation member overlaps the first molding member in a vertical direction.

12. The semiconductor package according to claim 1, wherein the heat dissipation member includes thermal interface material (TIM).

13. A semiconductor package comprising:
a redistribution layer (RDL) including a redistribution wiring structure;
a first semiconductor chip on the RDL and electrically connected to the redistribution wiring structure;
a heat dissipation member in contact with an upper surface of the first semiconductor chip;
a conductive post on the RDL and spaced apart from the first semiconductor chip in a horizontal direction, wherein the conductive post is electrically connected to the redistribution wiring structure;
a first molding member on the RDL and configured to cover sidewalls of the first semiconductor chip, the heat dissipation member, and the conductive post;
a bonding layer structure in contact with upper surfaces of the first molding member, the heat dissipation member, and the conductive post;
the bonding layer structure including a bonding pattern structure in the bonding layer structure, the bonding pattern structure in contact with the upper surface of the conductive post;
a package substrate in contact with upper surfaces of the bonding layer structure and the bonding pattern structure;
a second semiconductor chip on and electrically connected to the package substrate; and
a second molding member on the package substrate, the second molding member configured to cover the second semiconductor chip.

14. The semiconductor package according to claim 13, wherein the upper surface of the first molding member is substantially coplanar with the upper surface of the heat dissipation member.

15. The semiconductor package according to claim 13, wherein the bonding layer structure includes silicon carbonitride or silicon oxide, and
wherein the bonding pattern structure includes copper.

16. A semiconductor package comprising:
a redistribution layer (RDL) including a redistribution wiring structure;
a first semiconductor chip on the RDL and electrically connected to the redistribution wiring structure;
a conductive post on the RDL and spaced apart from the first semiconductor chip in a horizontal direction, wherein the conductive post is electrically connected to the redistribution wiring structure;
a first molding member on the RDL, the first molding member including:
a first portion configured to cover a sidewall of the first semiconductor chip, the first portion having a first upper surface; and
a second portion configured to cover a sidewall of the conductive post, the second portion having a second upper surface that is lower than the first upper surface of the first portion;
a package substrate on the first semiconductor chip and the first molding member and electrically connected to the conductive post;
a second semiconductor chip on and electrically connected to the package substrate; and
a second molding member on the package substrate and configured to cover the second semiconductor chip.

17. The semiconductor package according to claim 16, further comprising a heat dissipation member in contact with an upper surface of the first semiconductor chip.

18. The semiconductor package according to claim 17, wherein a portion of the heat dissipation member contacts the first upper surface of the first portion of the first molding member.

19. The semiconductor package according to claim 16, further comprising a conductive connection member in contact with an upper surface of the conductive post and a lower surface of the package substrate.

20. The semiconductor package according to claim 19, wherein a lower surface of the conductive connection member is lower, in a vertical direction, than an upper surface of the first semiconductor chip.
